(19) United States
(12) Patent Application Publication
(10) Pub. No.: US 2015/0187726 A1
(43) Pub. Date: Jul. 2, 2015

(54) SEMICONDUCTOR PACKAGE AND METHOD FOR MANUFACTURING THE SAME

(71) Applicant: SAMSUNG ELECTRO-MECHANICS CO., LTD., Suwon-Si (KR)

(72) Inventors: Sung Keun PARK, Suwon-Si (KR); Jun Woo Myung, Suwon-Si (KR); Sung Min Song, Suwon-si (KR)

(73) Assignee: SAMSUNG ELECTRO-MECHANICS CO., LTD., Suwon-Si (KR)

(21) Appl. No.: 14/582,196

(22) Filed: Dec. 24, 2014

(30) Foreign Application Priority Data
Dec. 31, 2013 (KR) 10-2013-0168758

(51) Int. Cl. H01L 23/00; H01L 23/495

(52) U.S. Cl. CPC H01L 24/33; H01L 23/495; H01L 24/49; H01L 2924/014; H01L 2924/01028; H01L 2924/01047; H01L 2924/01079; H01L 2924/351

(57) ABSTRACT

There are provided a semiconductor package and a method for manufacturing the same. The semiconductor package according to an exemplary embodiment of the present disclosure includes: a board on which an insulating layer and a plurality of circuit patterns are formed; first bonding parts formed on portions of an upper portion of the circuit pattern; second bonding parts formed on portions of the upper portion of the circuit pattern; a first semiconductor device mounted on the board; a first connecting member of electrically connecting the first bonding part and the first semiconductor device to each other; a second connecting member having one surface bonded to the second bonding part and the other end exposed to the outside; and an oxide film formed on the remaining portions except for the first bonding part and the second bonding part.

### CROSS-REFERENCE TO RELATED APPLICATION

This application claims the foreign priority benefit of Korean Patent Application No. 10-2013-0168758, filed on Dec. 31, 2013, entitled “Semiconductor Package Module and Method for Manufacturing the Same” which is hereby incorporated by reference in its entirety into this application.

### BACKGROUND

Embodiments of the present disclosure relate to a semiconductor package and a method for manufacturing the same.

A semiconductor package is configured to include a circuit component for power, a control circuit component, a lead frame, a heat dissipation substrate, and a sealing resin.

In developing the semiconductor package, heat dissipation characteristics of a board is important in terms of reliability including a lifespan of power devices (e.g., an insulated gate bipolar transistor (IGBT), a diode, and the like).

In addition, as semiconductor devices become high speed and high output, many developments for treating heat generated from the semiconductor package have been demanded.

Accordingly, in order to improve the heat dissipation characteristics of the board, a structure has been used in which a metal material is used as a base of the board and a metal base and a copper foil for forming a circuit are bonded by prepreg or a metal oxide layer.

In order to solder and bond devices on circuit patterns of the metal board formed as described above, a temperature of the board should be increased to a solder melting temperature or more. After the devices are soldered and bonded onto the board, a reflow process of cooling the board to a room temperature is performed.

### RELATED ART DOCUMENT

### Patent Document

(Patent Document 1) U.S. Patent Application Publication No. 2012-0111610

### SUMMARY

An aspect of the present disclosure may provide a semiconductor package having high reliability by reducing a delamination phenomenon between a package substrate and a molding member and increasing adhesion, and a method for manufacturing the same.

An aspect of the present disclosure may also provide a semiconductor package capable of preventing process defect caused by a solder diffusion or spatter phenomenon when an electronic device or a lead frame is bonded onto the board by a soldering, and a method for manufacturing the same.

An aspect of the present disclosure may also provide a semiconductor package capable of simplifying processes as compared to the existing processes in forming a plating layer having excellent adhesive property and conductivity in a bonding part to increase adhesion when performing a wire bonding of electrically connecting the board and the electronic device to each other.

According to an aspect of the present disclosure, a semiconductor package may include: a board on which an insulating layer and a plurality of circuit patterns are formed; first bonding parts formed on portions of an upper portion of the circuit pattern; second bonding parts formed on portions of the upper portion of the circuit pattern; a first semiconductor device mounted on the board; a first connecting member of electrically connecting the first bonding part and the first semiconductor device to each other; a second connecting member having one surface bonded to the second bonding part and the other end exposed to the outside; and an oxide film formed on the remaining portions except for the first bonding part and the second bonding part.

The first semiconductor device may be a power device.

The semiconductor package may further include a third bonding part formed between the circuit pattern and the first semiconductor device.

The semiconductor package may further include a second semiconductor device mounted on the board.

The second semiconductor device may be a power device or a control device.

The first connecting member may be a wire or a lead frame.

The second connecting member may be a lead frame.

The first bonding part may be plated by selecting one or more of silver (Ag), nickel (Ni), or gold (Au).

The second bonding part may be a solder paste.

The oxide film may be silica (SiO₂) or liquid phase titanium sol-gel (Ti Sol-Gel).

According to another aspect of the present disclosure, a method for manufacturing a semiconductor package may include: preparing a board on which an insulating layer and circuit patterns are formed; forming first bonding parts and second bonding parts on portions of an upper portion of the circuit pattern; mounting a first semiconductor device on the circuit pattern; connecting, by a first connecting member, the first bonding part and the first semiconductor device so as to be electrically connected to each other; connecting a second connecting member having the other end exposed to the outside to the second bonding member; and forming an oxide film on the remaining portions except for the first bonding part and the second bonding part.

The forming of the oxide film may be performed by any one of a sputtering method, a chemical vapor deposition (CVD), and an aerosol deposition (AD).

The method may further include, forming a patterned mask on the circuit pattern so that a region in which the oxide film is to be formed is exposed, before the forming of the oxide film, and removing the mask after the forming of the oxide film.

A material of the mask may be selected from a metal, a film, and a liquid phase polymer material.

The first semiconductor device may be a power device.

The forming of the first bonding parts and the second bonding parts may include forming third bonding parts on portions of the upper portion of the circuit pattern.

In the mounting of the first semiconductor device, the first semiconductor device may be mounted on the third bonding part.

The method may further include, after the preparing of the board, mounting a second semiconductor device.

The second semiconductor device may be a power device or a control device.

The first connecting member may be a wire or a lead frame.

The second connecting member may be a lead frame.

The first bonding part may be plated by selecting one or more of silver (Ag), nickel (Ni), or gold (Au).

The second bonding part may be applied with a solder paste.

The oxide film may be silica (SiO₂) or liquid phase titanium sol-gel (Ti Sol-Gel).

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view schematically showing a structure of a semiconductor package according to an exemplary embodiment of the present disclosure; and

FIGS. 2 through 7 are cross-sectional views sequentially showing a method for manufacturing a semiconductor package according to an exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

### Semiconductor Package

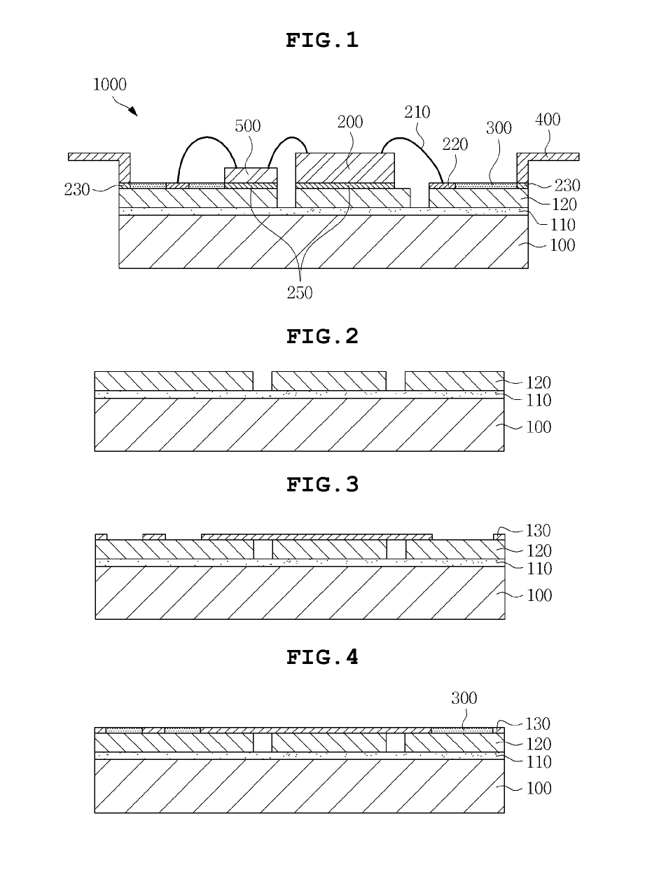

FIG. 1 is a cross-sectional view schematically showing a structure of a semiconductor package according to an exemplary embodiment of the present disclosure.

Referring to FIG. 1, a semiconductor package 1000 according to an exemplary embodiment of the present disclosure may include a board 100 on which an insulating layer 110 and a plurality of circuit patterns 120 are formed, first bonding parts 220 formed on portions of an upper portion of the circuit pattern 120, second bonding parts 230 formed on portions of the upper portion of the circuit pattern 120, a first semiconductor device 200 mounted on the board 100, a first connecting member 210 of electrically connecting the first bonding part 220 and the first semiconductor device 200 to each other, a second connecting member 400 having one surface bonded to the second bonding part 230 and the other surface exposed to the outside, and an oxide film 300 formed on the remaining portions except for the first bonding part 220 and the second bonding part 230.

Here, the board 100 may be a printed circuit board, a ceramic substrate, or a metal board having an anodized layer, but is not particularly limited thereto.

The board, which is a circuit board on which at least one circuit layer including a connection pad is formed on the insulating layer, may be the printed circuit board. Although FIG. 1 shows a case in which specific inner layer circuit configurations are omitted for convenience of explanation, it may be sufficiently recognized by those skilled in the art that a typical circuit board having at least one circuit layer formed on the insulating layer is used as the board.

As the insulating layer, a resin insulating layer may be used. As a material of the resin insulating layer, a thermo-setting resin such as an epoxy resin, a thermo-plastic resin such as a polyimide, or a resin having a reinforcement material such as a glass fiber or an inorganic filler impregnated in the thermo-setting resin and the thermo-plastic resin, for example, prepreg may be used. In addition, a thermo-setting resin, a photo-curable resin, and/or the like may be used. However, the material of the resin insulating layer is not particularly limited thereto.

The circuit including the connection pad may be made of any material without being limited as long as it is used as a conductive metal for the circuit in a field of circuit board, and is typically made of copper in the case of the printed circuit board.

The ceramic substrate may be made of metal based nitride or a ceramic material. For example, the metal based nitride may include aluminum nitride (AlN) or silicon nitride (SiN) and the ceramic material may include aluminum oxide (Al₂O₃) or beryllium oxide (BeO), but are not particularly limited thereto.

Meanwhile, the metal board may be made of any one selected from aluminum (Al), an aluminum (Al) alloy, copper (Cu), iron (Fe), an iron-nickel (Fe—Ni) alloy, or titanium (Ti), and may be made of aluminum (Al) or the aluminum alloy having very excellent thermal transfer characteristics as a metal material capable of easily being obtained at low cost.

In addition, the anodized layer which is, for example, formed by immersing the metal board made of aluminum or the aluminum alloy in an electrolyte solution such as boric acid, phosphoric acid, sulfuric acid, chromic acid, or the like, and then applying an anode to the metal board and applying a cathode to the electrolyte solution, has insulation characteristics and relatively high thermal transfer characteristics of about 10 to 30 W/mk.

As described above, the anodized layer made of aluminum or the aluminum alloy may be an aluminum anodized film (Al₂O₃) 300.

Since the anodized layer has insulation characteristics, it enables a circuit layer to be formed on the board. In addition, since the anodized layer may be formed at a thickness thinner than that of a general insulating layer, it enables thinness simultaneously with further improving heat dissipation performance.

The semiconductor package 1000 according to an exemplary embodiment of the present disclosure may further include a third bonding part 250 formed between the circuit pattern 120 and the first semiconductor device 200. The third bonding part 250 may be formed on portions of the upper portion of the circuit pattern 120.

The circuit pattern 120 and the first semiconductor device 200 may be a power device. For example, the power device may be a device having high heating value such as a silicon controlled rectifier (SCR), a power transistor, an insulated gate bipolar transistor (IGBT), a metal oxide semiconductor (MOS) transistor, a power rectifier, a power regulator, an inverter, a converter, or a high power semiconductor chip or diode including a combination thereof, or the like.

In addition, a second semiconductor device 500 may be further mounted on the board 100.

The second semiconductor device 500 may be the power device having high heating value such as the first semiconductor device 200 and may be a control device having low heating value such as a control integrated circuit (IC). Although FIG. 1 shows a case in which the second semiconductor device 500 is mounted on the circuit pattern 120, the present disclosure is not limited thereto. In the case in which the second semiconductor device 500 is the control device, since it has low heating value, it may be mounted on the lead frame disposed around the board according to a design intended by a designer.

According to an exemplary embodiment of the present disclosure, a plurality of circuit patterns 120 may be formed. Therefore, the first semiconductor device 200 and the second semiconductor device 500 may be each mounted on different circuit patterns 120. Alternatively, the first semiconductor device 200 and the second semiconductor device 500 may be mounted on the same circuit pattern 120, if necessary.

Although FIG. 1 schematically shows the first semiconductor device 200 and the second semiconductor device 500 in which other detailed components thereof are omitted, it may be sufficiently recognized by those skilled in the art that all semiconductor device structures known in the art are not particularly limited and may be applied to the semiconductor package according to the present disclosure.

The first connecting member 210 having the first bonding part 220 on the circuit pattern 120 of the board 100 and electrically connecting the board and the semiconductor device to each other may be the lead frame or a wire.

The first bonding part 220 on the circuit pattern 120, which is a plating layer having a plating formed thereon, may be plated by selecting one or more of silver (Ag), nickel (Ni), or gold (Au).

Here, as the first connecting member 210, the wire may be used and made of aluminum (Al), gold (Au), copper (Cu), or the like.

However, the material of the wire is not particularly limited thereto, and the wire applying a rating voltage of a high voltage to the electronic device, which is the power device, is generally made of aluminum (Al). The reason is that it is efficient to use aluminum (Al) in view of cost reduction as compared to a case of using gold (Au) or copper (Cu) because a thick wire needs to be used to withstand a high voltage.

In addition, the lead frame may be made of any one selected from copper (Cu), iron (Fe), or an iron-nickel (Fe—Ni) alloy, but is not particularly limited thereto.

The second connecting member 400 having the second bonding part 230 on the circuit pattern 120 of the board 100 and electrically connecting the board and the outside to each other may be a typical lead frame.

The second bonding part 230 on the circuit pattern 120 of the board may be a part for forming a solder paste. The first semiconductor device 200 and the second semiconductor device 500 as described above as well as the second connecting member 400 of electrically connecting the board and the outside to each other by the solder paste, which is the second bonding part 230 may be bonded to the board.

The soldering may use a Sn—Pb eutectic solder or a lead-free solder such as Sn—Ag—Cu, for example. In addition, the soldering method may be performed by a solder paste applying process using a metal mask. However, the soldering method is not limited thereto.

Here, the second connecting member 400 may be the lead frame, where the lead frame may be made of any one selected from copper (Cu), iron (Fe), or an iron-nickel (Fe—Ni) alloy, but is not particularly limited thereto.

Here, the semiconductor package 1000 according to an exemplary embodiment of the present disclosure includes an oxide film 300 formed on the remaining portions except for the first bonding part 220 and the second bonding part 230 on the circuit pattern 120 of the board.

The oxide film 300 may be made of silica (SiO₂) or titanium sol-gel (Ti Sol-Gel) of a liquid phase.

The oxide film 300 may be formed by any one selected from a sputtering method, a chemical vapor deposition (CVD), and an aerosol deposition (AD).

By forming the oxide film 300, the circuit pattern 120 of the board may be blocked and protected from the outside, and a phenomenon in which a delamination phenomenon is caused between the circuit pattern 120 of the board and the molding member when a molding is performed for the circuit pattern 120 itself according to the related art may be solved.

By forming the plating layer, which is the first bonding part 220, on the oxide film 300 formed in the pattern, bonding open defect which may occur upon performing a bonding process between the wire and the board may be solved.

In addition, in forming the oxide film 300 and then forming the second bonding part 230, process defect caused by a solder diffusion or spatter phenomenon upon forming the solder paste, which is the second bonding part 230, may be prevented.

### Method for Manufacturing Semiconductor Package

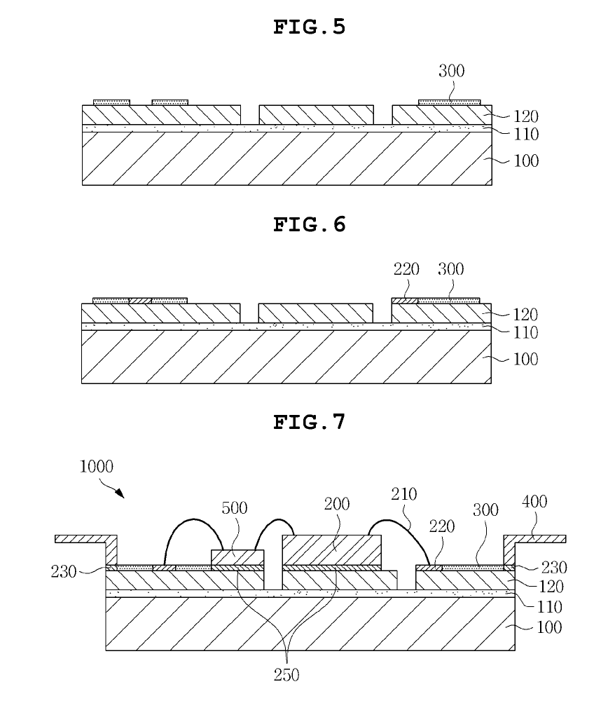

FIGS. 2 through 7 are cross-sectional views sequentially showing a method for manufacturing a semiconductor package according to an exemplary embodiment of the present disclosure.

First, referring to FIG. 2, a board on which an insulating layer and circuit patterns 120 are formed is prepared.

The board 100 may be a printed circuit board, a ceramic substrate, or a metal board having an anodized layer, but is not particularly limited thereto.

The board 100, which is a circuit board that one or more circuit layers are formed, may be the printed circuit board. Although FIG. 2 shows a case in which specific inner layer circuit configurations are omitted for convenience of explanation, it may be sufficiently recognized by those skilled in the art that a typical circuit board having at least one circuit layer formed on the insulating layer is used as the board.

As the insulating layer 110, a resin insulating layer may be used. As a material of the resin insulating layer, a thermo-setting resin such as an epoxy resin, a thermo-plastic resin such as a polyimide resin, or a resin having a reinforcement material such as a glass fiber or an inorganic filler impregnated in the thermo-setting resin and the thermo-plastic resin, for example, prepreg may be used. In addition, a thermo-setting resin, a photo-curable resin, and/or the like may be used. However, the material of the resin insulating layer is not particularly limited thereto.

The ceramic substrate may be made of metal based nitride or a ceramic material. For example, the metal based nitride may include aluminum nitride (AlN) or silicon nitride (SiN) and the ceramic material may include aluminum oxide (Al₂O₃) or beryllium oxide (BeO), but are not particularly limited thereto.

Meanwhile, the metal board may be made of any one selected from aluminum (Al), an aluminum (Al) alloy, copper (Cu), iron (Fe), an iron-nickel (Fe—Ni) alloy, or titanium (Ti), and may be made of aluminum (Al) or the aluminum alloy having very excellent thermal transfer characteristics as a metal material capable of easily being obtained at low cost.

In addition, the anodized layer which is formed by immersing the metal board made of aluminum or the aluminum alloy in an electrolyte solution such as boric acid, phosphoric acid, sulfuric acid, chromic acid, or the like, and then applying an anode to the metal board and applying a cathode to the electrolyte solution, has insulation characteristics and relatively high thermal transfer characteristics of about 10 to 30 W/mk.

As described above, the anodized layer made of aluminum or the aluminum alloy may be an aluminum anodized film (Al₂O₃) 300.

Since the anodized layer has insulation characteristics, it enables a circuit layer to be formed on the board 100. In addition, since the anodized layer may be formed at a thickness thinner than that of a general insulating layer, it enables thinness simultaneously with further improving heat dissipation performance.

Next, referring to FIGS. 3 through 5, oxide films 300 are formed on portions except for a first bonding part 220 and a second bonding part 230 of the board to be described below.

Before the forming of the oxide film 300, patterned masks 130 are formed so that regions on which the oxide films 300 will be formed on the circuit pattern 120 are exposed.

The exposed portions are the portions on which the oxide films 300 will be formed, and other portions may be a plating layer, which is the first bonding part 220 and a part for forming a solder paste, which is the second bonding part 230.

The first bonding part 220 to be described below, which is a portion that the wire of electrically connecting the semiconductor device and the board to each other is bonded to the circuit pattern 120 of the board, is plated, thereby making it possible to further increase a plating strength thereof than before.

In addition, the second bonding part 230, which is the part for forming the solder paste, may mount a first semiconductor device 200, a second semiconductor device 500, and a lead frame which are to be described below on the board by the soldering.

In addition, as a method for increasing adhesion together with the solder paste, an underfill solution may be used, where the underfill solution is generally made of a thermo-setting resin such as an epoxy resin, a phenol resin, a melamine resin, a ketone resin, or the like, or a precursor (a cured or semi-cured thermo-setting resin) thereof, but may be particularly made of the epoxy resin. The underfill solution has high fluidity, may be easily filled even in a narrow space, may easily be treated, and may exhibit strong and excellent mechanical characteristics after being cured. Examples of the epoxy resin may include an epoxy resin of a bisphenol form, an epoxy resin of a novolak form, an epoxy resin of a naphthalene form, an epoxy resin of a biphenyl form, an epoxy resin of a cyclopentadiene form, and the like. One kind of these epoxy resins may be solely used and two or more resins thereof may be mixed and used.

Here, the mask 130 may be made of any one selected from a metal, a film, and a liquid phase polymer material.

The mask 130 made of at least any one metal of copper (Cu), chrome (Cr), titanium (Ti), nickel (Ni), or an alloy thereof, and may be made of a dry film photoresist or a liquid phase photosensitive resist material.

After forming the mask 130, the oxide film 300 is formed on the mask 130.

Here, a material of the oxide film 300 is silica (SiO₂) or a liquid phase titanium sol-gel (Ti Sol-Gel), and as a method for forming the oxide film 300, a sputtering method which is already well known may be performed, and may be selected from a chemical vapor deposition (CVD) and an aerosol deposition (AD).

Here, the CVD is generally an industrial method in which a thin film such as silicon is manufactured on the board 100 in a manufacturing process of an integrated circuit (IC), or the like.

The CVD is used for manufacturing a silicon oxide film 300, a silicon nitrogen film, an amorphous silicon thin film, or the like. The CVD is referred to as a chemical vapor phase epitaxy since it uses chemical reaction in a manufacturing process. When gas containing chemistries is applied with energy by heat or light or is brought into a plasma state by a high frequency, a raw material is brought into a radical state and reactivity is significantly increased, such that it is absorbed and deposited on the board.

Here, the aerosol deposition (AD) refers to a method in which a film is manufactured by colliding solid particles of the raw material on the board at a high speed using the solid particles of the raw material at a room temperature.

The above-mentioned technology may manufacture a thick film of several hundreds μm as well as a thin film of 1 μm or less at a room temperature in a short time.

After the oxide film 300 is formed on the exposed portion of the patterned mask 130, the mask 130 is removed.

Next, referring to FIG. 6, a plating layer, which is a first bonding part 220, which is a portion to which the wire connecting the board and the semiconductor device to each other is bonded, is formed.

In this case, the plating layer may be formed by arbitrarily designating a bonding part of the wire connecting the board 100 and the semiconductor device to each other on design as in the present exemplary embodiment, or the semiconductor device may be first mounted and the plating layer may be then formed.

In this case, the first bonding part 220, which is the plating layer plated by selecting one or more of silver (Ag), nickel (Ni), or gold (Au), may increase adhesion with the wire by forming the plating layer.

Next, referring to FIG. 7, the first semiconductor device 200 and the second semiconductor device 500 are mounted on the board.

The first semiconductor device 200 may include a power device and a control device, but is not limited thereto. For example, the power device may be a device having high heating value such as a silicon controlled rectifier (SCR), a power transistor, an insulated gate bipolar transistor (IGBT), a metal oxide semiconductor (MOS) transistor, a power rectifier, a power regulator, an inverter, a converter, a high power semiconductor chip or diode including a combination thereof, or the like.

The second semiconductor device 500 may be the power device having high heating value such as the first semiconductor device 200 and may be a control device having low heating value such as a control integrated circuit (IC). Since the control device has a low heating value, it may be mounted on the lead frame disposed around the board 100 according to a design intended by a designer.

Although FIG. 7 schematically shows the first semiconductor device 200 and the second semiconductor device 500 in which other detailed components thereof are omitted, it may be sufficiently recognized by those skilled in the art that all semiconductor device structures known in the art are not particularly limited and may be applied to the semiconductor package 1000 according to the present disclosure.

According to an exemplary embodiment of the present disclosure, before the first semiconductor device 200 and the second semiconductor device 500 are mounted, a second bonding part 230 and a third bonding part 250 may be formed on the circuit pattern 120. Here, the third bonding part 250 may be formed on positions on which the first semiconductor device 200 and the second semiconductor device 500 are mounted.

In an exemplary embodiment of the present disclosure, the second bonding part 230 and the third bonding part 250 are made of a solder. That is, the second bonding part 230 and the second connecting member 400 may be bonded to each other by a soldering bonding. In addition, the first semiconductor device 200 and the second semiconductor device 500 may also be bonded to the third bonding part 250 by the soldering bonding. However, a material of the third bonding part 250 is not limited to the solder. That is, the third bonding part 250 may be made of any material of adhesive materials used in a field of circuit board. The soldering bonding may use a Sn—Pb eutectic solder or a lead-free solder such as Sn—Ag—Cu, for example. In addition, the soldering method may be performed by a solder paste applying process using a metal mask. However, the soldering method is not limited thereto.

In addition, the first semiconductor device 200 and the second semiconductor device 500 may be connected to the board 100 by a first connecting member 210, and the first connecting member 210 is bonded to the plating layer, which is the first bonding part 220.

The plating layer, which is the first bonding part 220 is a plating layer having a plating formed thereon, may be plated by selecting one or more of silver (Ag), nickel (Ni), or gold (Au).

Here, the first connecting member 210 may be a wire or a lead frame.

However, the first connecting member is not particularly limited thereto, and the wire applying a rating voltage of a high voltage to the electronic device, which is the power device, is generally made of aluminum (Al). The reason is that it is efficient to use aluminum (Al) in view of cost reduction as compared to a case of using gold (Au) or copper (Cu) because a thick wire needs to be used to withstand a high voltage.

In addition, the lead frame may be made of any one selected from copper (Cu), iron (Fe), or an iron-nickel (Fe—Ni) alloy, but is not particularly limited thereto.

The second connecting member 400 may be bonded onto the board by the solder paste bonding to the second bonding part 230 of the board 100, where the second connecting member 400 may be the lead frame.

The lead frame, which is the second connecting member 400, is included in the semiconductor package 1000 and has the other side protruded to the outside.

The lead frame may be mounted on the board by disposing it around the board or performing the solder bonding by the solder paste, which is the second connecting member 400.

Although FIG. 7 shows the lead frame in which a step part is not formed, one or more step parts may be additionally formed.

In this case, the lead frame may be made of any one selected from copper (Cu), iron (Fe), or an iron-nickel (Fe—Ni) alloy, but is not particularly limited thereto.

In addition, the second semiconductor device 500 may be further bonded to the lead frame.

Although not shown in FIG. 7, an oxide film 300 protecting the circuit pattern 120 of the board and a molding part surrounding and covering the semiconductor devices may be further formed.

The molding part is formed in a form in which it is filled in an upper portion of the board.

In case of the oxide film 300, an occurrence of a problem such as delamination between the board and a molding material, or the like is decreased as compared to the circuit pattern 120 according to the related art, thereby making it possible to improve long term reliability of the board.

In this case, the molding part may be a thermo-plastic resin or a thermo-setting resin.

The thermo-plastic resin, which is a resin capable of being easily reused, has a short molding time needed to cure as compared to the thermo-setting resin.

Since heat is blocked due to the molding, heat dissipation effect may be further improved.

In addition, since a method for bonding the board 100 and the lead frame by an injection molding using the thermo-plastic resin performs a process which maintaining a constant process temperature, it may prevent warpage of the board 100.

After performing the injection molding using the thermo-plastic resin, an incapsulation process using the thermo-setting resin may be additionally performed.

In this case, the molding part may be made of silicone gel, an epoxy molded compound (EMC), or the like, but is not particularly limited thereto.

By forming the oxide film 300 on the circuit pattern 120 as described above, the circuit pattern 120 of the board may be blocked and protected from the outside, and a phenomenon in which a delamination phenomenon is caused between the circuit pattern 120 of the board and the molding member when the molding is performed for the circuit pattern 120 itself according to the related art may be solved.

By forming the plating layer, which is the first bonding part 220, on the oxide film 300 formed in the pattern, bonding open defect which may occur upon performing a bonding process between the wire and the board 100 may be solved.

In addition, in forming the oxide film 300 and then forming the second bonding part 230, process defect caused by a solder diffusion or spatter phenomenon upon forming the solder paste, which is the second bonding part 230, may be prevented.

According to the exemplary embodiment of the present disclosure, the semiconductor package and the method for manufacturing the same may solve bonding open defect which may occur upon performing the wire bonding process.

In addition, the delamination phenomenon between the board and the molding member may be decreased.

In addition, the process defect caused by the solder diffusion or spatter phenomenon upon performing the soldering bonding may be prevented.

In addition, processes may be simplified and the time may be shortened.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A semiconductor package comprising:
a board on which an insulating layer and a plurality of circuit patterns are formed;
first bonding parts formed on portions of an upper portion of the circuit pattern;
second bonding parts formed on portions of the upper portion of the circuit pattern;
a first semiconductor device mounted on the board;
a first connecting member of electrically connecting the first bonding part and the first semiconductor device to each other;
a second connecting member having one surface bonded to the second bonding part and the other end exposed to the outside; and
an oxide film formed on the remaining portions except for the first bonding part and the second bonding part.

2. The semiconductor package of claim 1, wherein the first semiconductor device is a power device.

3. The semiconductor package of claim 1, further comprising a third bonding part formed between the circuit pattern and the first semiconductor device.

4. The semiconductor package of claim 1, further comprising a second semiconductor device mounted on the board.

5. The semiconductor package of claim 4, wherein the second semiconductor device is a power device or a control device.

6. The semiconductor package of claim 1, wherein the first connecting member is a wire or a lead frame.

7. The semiconductor package of claim 1, wherein the second connecting member is a lead frame.

8. The semiconductor package of claim 1, wherein the first bonding part is plated by selecting one or more of silver (Ag), nickel (Ni), or gold (Au).

9. The semiconductor package of claim 1, wherein the second bonding part is a solder paste.

10. The semiconductor package of claim 1, wherein the oxide film is silica (SiO₂) or liquid phase titanium sol-gel (Ti Sol-Gel).

11. A method for manufacturing a semiconductor package, the method comprising:
preparing a board on which an insulating layer and circuit patterns are formed;
forming first bonding parts and second bonding parts on portions of an upper portion of the circuit pattern;
mounting a first semiconductor device on the circuit pattern;
connecting, by a first connecting member, the first bonding part and the first semiconductor device so as to be electrically connected to each other;
connecting a second connecting member having the other end exposed to the outside to the second bonding member; and
forming an oxide film on the remaining portions except for the first bonding part and the second bonding part.

12. The method of claim 11, wherein the forming of the oxide film is performed by any one of a sputtering method, a chemical vapor deposition (CVD), and an aerosol deposition (AD).

13. The method of claim 11, further comprising, forming a patterned mask on the circuit pattern so that a region in which the oxide film is to be formed is exposed, before the forming of the oxide film, and removing the mask after the forming of the oxide film.

14. The method of claim 13, wherein a material of the mask is selected from a metal, a film, and a liquid phase polymer material.

15. The method of claim 11, wherein the first semiconductor device is a power device.

16. The method of claim 11, wherein the forming of the first bonding parts and the second bonding parts includes forming third bonding parts on portions of the upper portion of the circuit pattern.

17. The method of claim 16, wherein in the mounting of the first semiconductor device, the first semiconductor device is mounted on the third bonding part.

18. The method of claim 11, further comprising, after the preparing of the board, mounting a second semiconductor device.

19. The method of claim 18, wherein the second semiconductor device is a power device or a control device.

20. The method of claim 11, wherein the first connecting member is a wire or a lead frame.

21. The method of claim 11, wherein the second connecting member is a lead frame.

22. The method of claim 11, wherein the first bonding part is plated by selecting one or more of silver (Ag), nickel (Ni), or gold (Au).

23. The method of claim 11, wherein the second bonding part is applied with a solder paste.

24. The method of claim 11, wherein the oxide film is silica (SiO₂) or liquid phase titanium sol-gel (Ti Sol-Gel).
